(19) United States
(12) Patent Application Publication
(10) Pub. No.: US 2016/0211348 A1
(43) Pub. Date: Jul. 21, 2016

(54) TRENCH LATERAL DIFFUSION METAL OXIDE SEMICONDUCTOR DEVICE AND MANUFACTURING METHOD OF THE SAME

(71) Applicant: Maxchip Electronics Corp., Hsinchu City (TW)

(72) Inventor: Kosuke Yoshida, Hsinchu City (TW)

(21) Appl. No.: 14/601,242

(22) Filed: Jan. 21, 2015

(51) Int. Cl. H01L 29/66; H01L 29/06; H01L 29/78

(52) U.S. Cl. CPC H01L 29/66704; H01L 29/7825; H01L 29/7824; H01L 29/0653

(57) ABSTRACT

A trench lateral diffusion metal oxide semiconductor (LDMOS) device, disposed on a substrate, comprising: a transistor and an LDMOS transistor. The transistor has a gate. The LDMOS transistor has a trench gate, wherein the trench gate protrudes from a surface of the substrate. Electrical connection of the trench gate and a doping region due to a metal silicide may be prevented by protruding the trench gate from the surface of the substrate. And furthermore a step height difference between a gate and the trench gate may be decreased, and openings respectively exposing a top portion of the trench gate and a top portion of the gate may be formed without changing the manufacturing conditions.

### BACKGROUND OF THE INVENTION

1. Field of the Invention

The invention relates to a semiconductor device, and relates particularly to a trench lateral diffusion metal oxide semiconductor device and a manufacturing method of the same.

2. Description of Related Art

A lateral diffusion metal oxide semiconductor (LDMOS) device is a type of power source device widely used in a semiconductor manufacturing process. LDMOS transistors may provide a higher breakdown voltage (Vbd), and also may have a low on-resistance (Ron) during operations, therefore LDMOS transistors are widely used in power devices.

An LDMOS device may be complementarily integrated with a manufacturing process of a metal oxide semiconductor, thereby manufacturing a control switch, a logic switch and a power switch on a single wafer.

Along with increases in the integration of a semiconductor, currently industry has proposed a type of trench LDMOS transistor, having a trench gate disposed in a substrate. Conventional trench LDMOS transistors have a top portion of a trench gate normally lower than the surface of the substrate, therefore the depth of the opening exposing a top portion of the trench gate formed in an interlayer insulation layer is greater than the depth of the opening exposing a top portion of the planar gate. When forming openings of different depth, different manufacturing parameters are needed (for example, etching time or the like), as a result causing an increase in manufacturing costs and complicating the manufacturing steps of a trench LDMOS transistor.

Furthermore, a top portion of the trench gate is lower than the surface of the substrate, making the distance between the trench gate and source/drain regions small, and a short circuit will form between the trench gate and the source/drain regions due to the metal silicide manufacturing process.

### SUMMARY OF THE INVENTION

The invention provides a trench LDMOS device, a trench gate protrudes from a surface of the substrate, and electrical connection of the trench gate and a doped region due to metal silicide may be prevented, enhancing the performance of the device.

The invention provides a manufacturing method for a trench LDMOS device, the trench gate is formed protruding from a surface of the substrate to decrease a step height difference of the trench gate and the gate, and openings respectively exposing a top portion of the trench gate and a top portion of the gate may be formed without changing the manufacturing conditions.

The trench LDMOS device of the invention is disposed on a substrate, including: a transistor and a trench LDMOS transistor. The transistor is disposed on a first area of the substrate, the transistor having a gate. The trench LDMOS transistor is disposed on a second area of the substrate. The trench LDMOS transistor having a first well region, a second well region, a trench gate, a gate dielectric layer, a first doped region and a second doped region. The first doped region is disposed in the second area of the substrate. The second well region having a first conductivity type is disposed in the first well region. The trench gate is disposed in a trench of the substrate, wherein the trench gate protrudes from a surface of the substrate, and the trench is located in the second well region. The gate dielectric layer is disposed between the trench gate and the substrate. The first doped region having the first conductivity type is disposed in the substrate on two sides of the trench gate. The second doped region having a second conductivity type is disposed in the substrate between the trench gate and the first doped region.

In an embodiment of the invention, a step height of a portion of the trench gate protruding from the surface of the substrate is lower than a step height of the gate.

In an embodiment of the invention, a step height of a portion of the trench gate protruding from the surface of the substrate is higher than a step height of the gate.

In an embodiment of the invention, the trench LDMOS device has a spacer disposed on a side wall of a portion of the trench gate protruding from the surface of the substrate.

In an embodiment of the invention, the trench LDMOS device further includes: a third well region, a third doped region and an element isolation structure. The third well region having the second conductivity type is disposed in the first well region. The third doped region having the second conductivity type is disposed in the third well region. The element isolation structure is disposed in the substrate to isolate the second well region and the third well region.

In an embodiment of the invention, a depth of the trench is greater than a depth of a junction at a bottom of the second well region.

In an embodiment of the invention, the substrate is a silicon on insulator substrate. A bottom of the trench reaches an insulating layer of the silicon on insulator substrate.

In an embodiment of the invention, the trench LDMOS device further includes a plurality of trench isolation structures. The plurality of trench isolation structure are disposed in the substrate to isolate the first area and the second area, wherein each of the trench isolation structures respectively includes a conductive layer and a dielectric layer disposed between the conductive layer and the substrate.

In an embodiment of the invention, the LDMOS device further includes an embedded layer and a plurality of trench isolation structures. The embedded layer having the first conductive type, is disposed in the substrate, and located below the first well region. The plurality of trench isolation structures are disposed in the substrate, perforating the embedded layer to isolate the first area and the second area, wherein each of the trench isolation structures respectively includes an insulation layer and a fourth doped region disposed at a bottom of the insulating layer.

In an embodiment of the invention, the trench LDMOS device further includes a fifth doped region. The fifth doped region having the second conductivity connects two third doped regions respectively disposed in the third well regions on two sides of the second well region.

In an embodiment of the invention, the first well region alternately includes the first conductivity and the second conductivity along an extension direction of the trench gate.

In an embodiment of the invention, the trench LDMOS device further includes a sixth doped region. The sixth doped region having the first conductivity is connected two first doped regions respectively disposed in two adjacent second well regions.

A manufacturing method of a trench LDMOS device of the invention includes the following steps. A substrate having a first area and a second area is provided. A first well region is formed at the second area of the substrate. A second well region is formed in the first well region. A trench gate structure is formed at the second area of the substrate, the trench gate structure protrudes from a surface of the substrate, and is located in the second well region, wherein the trench gate structure includes a trench gate and a gate dielectric layer disposed between the trench gate and the substrate. A first doped region is formed on the surface of the substrate at two sides of the trench gate structure. A second doped region is formed on the surface of the substrate between the trench gate structure and the first doped region.

In an embodiment of the invention, a spacer is further formed on a side wall of a portion of the trench gate structure protruding from the surface of the substrate.

In an embodiment of the invention, the trench gate structure is formed at the second area of the substrate by the following steps. A patterned mask layer is formed on the substrate. A portion of the substrate is removed to form a trench in the substrate by using the patterned mask layer as a mask. The gate dielectric layer is formed on the surface of the trench. The patterned mask layer is removed. A conductive layer is formed to fill the trench on the substrate. The conductive layer is patterned to form the trench gate.

In an embodiment of the invention, the conductive layer is patterned, and a gate is formed at the first area of the substrate at the same time.

In an embodiment of the invention, the trench gate structure is formed at the second area of the substrate by the following steps. A first conductive layer is formed on the substrate. A patterned mask layer is formed on the first conductive layer. A portion of the first conductive layer and a portion of the substrate are removed to form a trench in the substrate by using the patterned mask layer as a mask. The patterned mask layer is removed. A dielectric layer is formed on the surface of the first conductive layer and the trench. A second conductive layer is formed to fill the trench on the substrate. The second conductive layer is removed to expose the dielectric layer. A portion of the dielectric layer is removed to form the gate dielectric layer, and the first conductive layer is patterned to form the trench gate.

In an embodiment of the invention, the first conductive layer is patterned, and a gate is formed at the first area of the substrate at the same time.

In an embodiment of the invention, the second conductive layer is removed by performing a chemical mechanical polishing process.

In an embodiment of the invention, the trench gate structure is formed at the second area of the substrate by the following steps. A first conductive layer is formed on the substrate. A sacrificial layer is formed on the first conductive layer. A patterned mask layer is formed on the sacrificial layer. A portion of the sacrificial layer, a portion of the first conductive layer and a portion of the substrate are removed to form a trench in the substrate by using the patterned mask layer as a mask. After the patterned mask layer is removed, the gate dielectric layer is formed on the trench. A second conductive layer is formed to fill the trench on the substrate. The second conductive layer is removed to expose the sacrificial layer. After the sacrificial layer is removed, the first conductive layer is patterned to form the trench gate.

In an embodiment of the invention, the first conductive layer is patterned and a gate is formed at the first area of the substrate at the same time.

In an embodiment of the invention, the second conductive layer is removed by performing a chemical mechanical polishing process.

In an embodiment of the invention, the trench gate structure is formed at the second area of the substrate by the following steps. A first conductive layer is formed on the substrate. A patterned mask layer is formed on the first conductive layer. A portion of the first conductive layer and a portion of the substrate are removed to form a trench in the substrate by using the patterned mask layer as a mask. The gate dielectric layer is formed on the surface of the trench. A second conductive layer is formed to fill the trench on the substrate. The second conductive layer is removed to expose the patterned mask layer. After the patterned mask layer is removed, the first conductive layer is patterned to form the trench gate.

In an embodiment of the invention, the first conductive layer is further patterned and a gate at the first area of the substrate is formed at the same time.

In an embodiment of the invention, the second conductive layer is removed by performing a chemical mechanical polishing process.

Based on the above, in the trench LDMOS device and manufacturing method thereof of the invention, a trench gate protruding from the surface of the substrate is formed to decrease a step height difference of the trench gate and the gate, and openings respectively exposing a top portion of the trench gate and a top portion of the gate may be formed without changing the manufacturing conditions.

Furthermore, a trench gate protrudes from a surface of the substrate, and electrical connection of the trench gate and a doped region due to a metal silicide may be prevented.

In addition, the gate dielectric layer of the trench LDMOS transistor does not produce an electric field, therefore leakage current may be prevented.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view illustrating a trench LDMOS device according to an embodiment of the invention.

FIG. 1B˜FIG. 1D are three dimensional structural schematics respectively illustrating a trench LDMOS device according to an embodiment of the invention.

FIG. 2˜FIG. 4 are cross-sectional views respectively illustrating a trench LDMOS device according to another embodiment of the invention.

FIG. 5A˜FIG. 5J are cross-sectional views illustrating a manufacturing process of a trench LDMOS device according to an embodiment of the invention.

FIG. 6A˜FIG. 6D are cross-sectional views illustrating a manufacturing process of a trench LDMOS device according to another embodiment of the invention.

FIG. 7A˜FIG. 7D are cross-sectional views illustrating a manufacturing process of a trench LDMOS device according to another embodiment of the invention.

FIG. 8A˜FIG. 8D are cross-sectional views illustrating a manufacturing process of a trench LDMOS device according to another embodiment of the invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

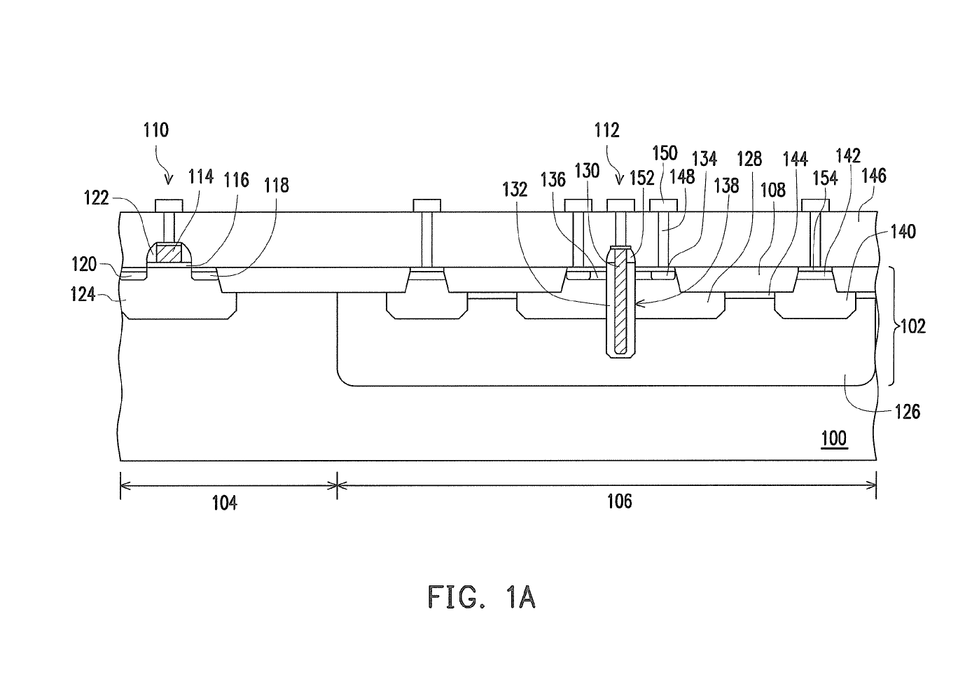

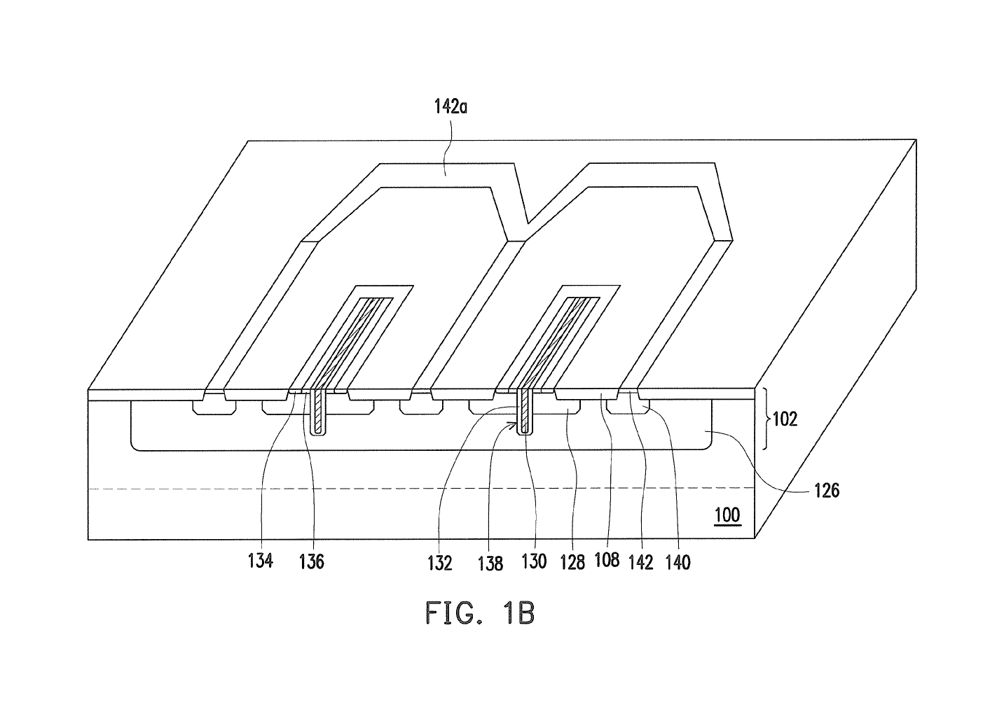

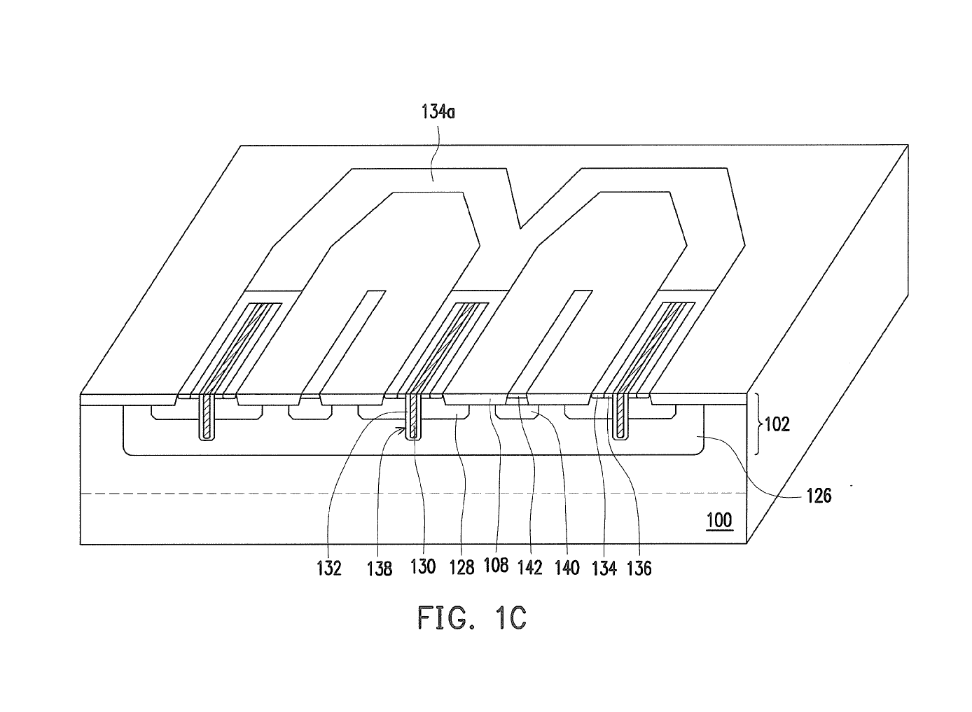

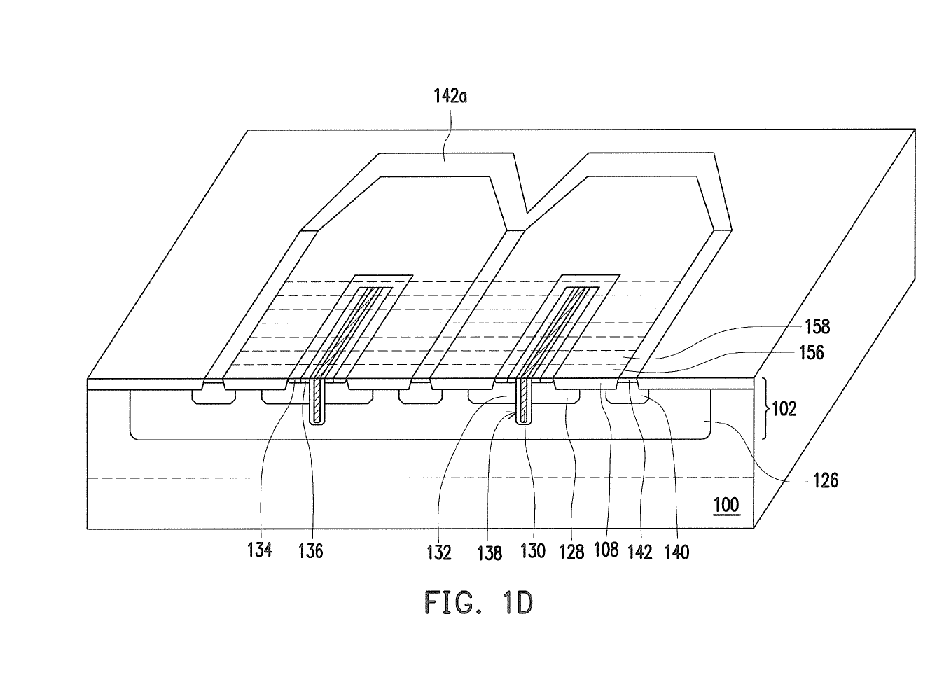

FIG. 1A is a cross-sectional view illustrating a trench LDMOS device according to an embodiment of the invention. FIG. 1B˜FIG. 1D are three dimensional structural schematics respectively illustrating a trench LDMOS device according to an embodiment of the invention. In FIG. 1B˜FIG. 1D, similar components with FIG. 1A are given the same reference numbers, and detailed description similar components will be omitted.

Referring to FIG. 1A, a trench LDMOS device is disposed on a substrate 100. The substrate 100 includes an epitaxial layer 102, and may be separated into a first area 104 and a second area 106, and an element isolation structure 108 formed in the substrate 100. The element isolation structure 108 for example is a shallow trench isolation structure.

The trench LDMOS device includes a transistor 110 and a trench LDMOS transistor 112.

The transistor 110, for example, is disposed at the first area 104 of the substrate 100. The transistor 110 includes a gate 114 (planar gate), a gate dielectric layer 116 and a source/drain region 118 and a source/drain region 120.

A material of the gate 114 includes conductive materials such as doped polysilicon or the like. A material of the gate dielectric layer 116, for example, is silicon oxide. A well region 124 is disposed, for example, below the transistor 110. The transistor 110 for example, is an N-type metal oxide semiconductor transistor or a P-type metal oxide semiconductor transistor. Based on the type of the transistor 110, the well region 124 may be an N-type well region or a P-type well region. A spacer 122 is disposed, for example, on a side wall of the gate 114. A material for the spacer 122 includes silicon oxide, silicon nitride, silicon oxynitride or the like.

The trench LDMOS transistor 112, for example, is disposed at the second area 106 of the substrate 100. The trench LDMOS transistor 112 includes: a well region 126, a well region 128, a trench gate 130, a gate dielectric layer 132, doped regions 134 and doped regions 136.

The well region 126, for example, is disposed in the second area 106 of the substrate 100. The well region 126 may be a first conductive well region or a second conductive well region (namely that is, an N-type well region or a P-type well region). The well region 128 has a first conductive type, disposed in the well region 126.

The trench gate 130, for example, is disposed in a trench 138 of the substrate 100, wherein the trench gate 130 protrudes from a surface of the substrate 100, and the trench 138 is located in the well region 128. The depth of the trench 138 is greater than the depth of the junction at the bottom of the well region 128. The step height of the portion of the trench gate 130 protruding from the surface of the substrate 100 may be higher or lower than the step height of the gate 114. A material of the trench gate 130 includes conductive materials such as doped poly-silicon or the like. There is a spacer 152 further disposed on the side wall of the portion of the trench gate 130 protruding from the surface of the substrate 100. A material of the spacer 152 includes silicon oxide, silicon nitride, silicon oxynitride or the like.

The gate dielectric layer 132, for example, is disposed between the trench gate 130 and the substrate 100. A material of the gate dielectric layer 132, for example, is silicon oxide. The doped region 134 has a first conductive type, and is disposed in the substrate 100 on two sides of the trench gate 130. The doped region 136 has a second conductive type, and is disposed in the substrate between the trench gate 130 and the doped region 134.

The trench LDMOS device further includes a well region 140 and a doped region 142. The well region 140 has a second conductive type, and is disposed in the well region 126. The doped region 142 has a second conductive type, and is disposed in the substrate 100 and is located on the well region 140. Wherein the well region 128 and the well region 140 are isolated by the element isolation structure 108. A surface field reducing diffusion layer 144 may be optionally disposed below the element isolation structure 108 between the well region 128 and the well region 140. The surface field reducing diffusion layer 144 may be a doped region of the first conductive type. In the trench LDMOS device, when the first conductive type is a P-type, then the second conductive type is an N-type; when the first conductive type is an N-type, then the second conductive type is a P-type.

The trench LDMOS device further includes an interlayer insulation layer 146, a plurality of plugs 148, and a plurality of conductive wires 150. The interlayer insulation layer 146 is disposed on the substrate 100. A material of the interlayer insulation layer 146, for example, is phosphorous silicate glass, boron phosphor silicate glass or the like. The plurality of conductive wires 150 are respectively disposed on the interlayer insulation layer 146. The plurality of conductive wires 150 are respectively electrically connected with the transistor 110 and each electrode of the trench LDMOS transistor 112 by being disposed on the plurality of plugs 148 in the interlayer insulation layer 146. A material of the conductive wires 150 and the plugs 148 include metal materials such as tungsten, copper, aluminium or the like.

A metal silicide layer 154 may be disposed on the surface of the gate 114, the source/drain region 118, the source/drain region 120, the trench gate 130, the doped region 134, the doped region 136 and the doped region 142.

In an embodiment, for example as shown in FIG. 1B, a trench LDMOS device has an outer drain layout, the doped region 142 of the well region 140 on two sides of the trench LDMOS transistor 112 are connected to each other by the doped region 142a having similar conductive type. The doped region 142a connects two doped regions 142 respectively disposed in the well regions 140 on two sides of the well region 128.

In an embodiment, as shown in FIG. 1C, a trench LDMOS device has an inner drain layout, the doped regions 134 on two sides of the well region 140 of the trench LDMOS transistor 112 are connected to each other by the doped region 134a having similar conductive type. The doped region 134a connects two doped regions 134 respectively disposed in two adjacent well regions 128.

In an embodiment, as shown in FIG. 1D, a trench LDMOS device has a super junction drain layout, the doped region 142 on two sides of the trench LDMOS transistor 112 are connected to each other by the doped region 142a having similar conductive type. The trench LDMOS transistor 112 includes a plurality of N-pillar regions 156 and P-pillar regions 158 in a staggered arrangement. In the N-pillar region 156, the well region 126 is an N-type well region; in the P-pillar region 158, the well region 126 is a P-type well region. The well region 126 alternately includes the first conductivity and the second conductivity along an extension direction of the trench gate 130.

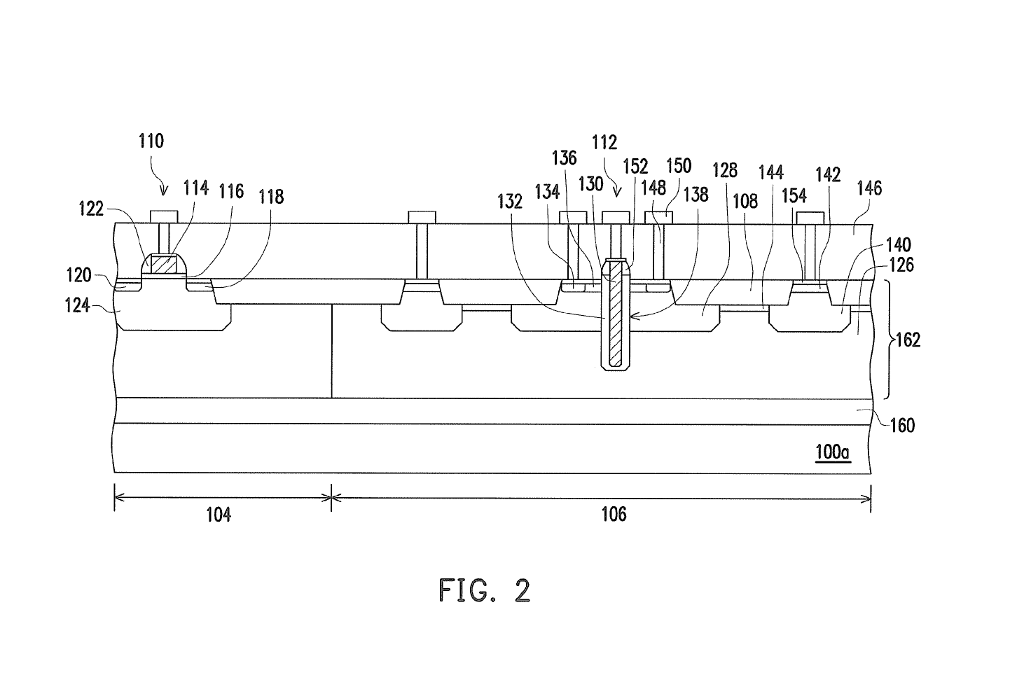

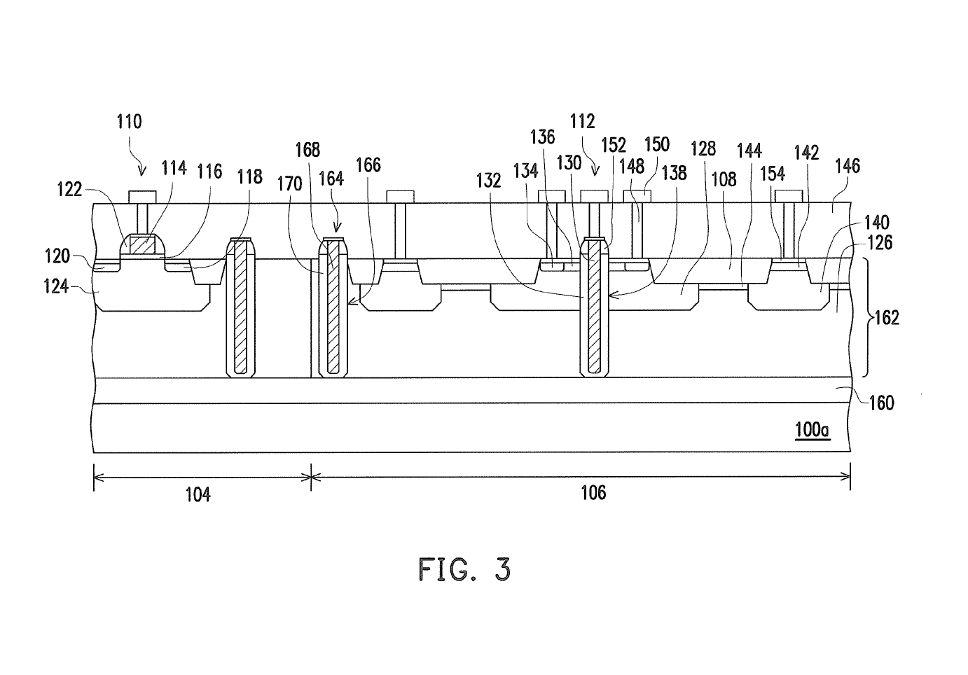

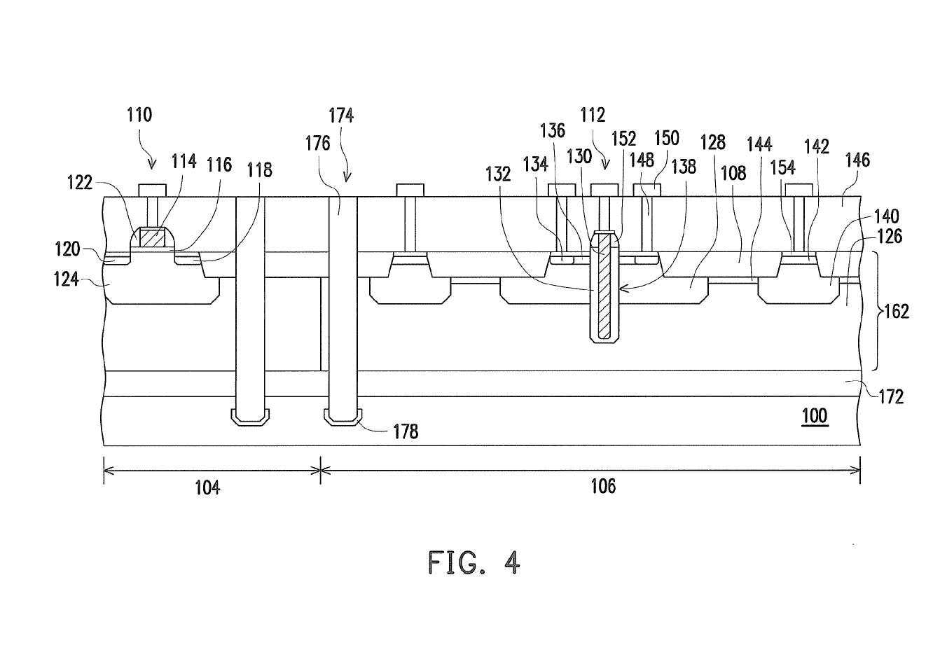

FIG. 2˜FIG. 4 are cross-sectional views respectively illustrating a trench LDMOS device according to another embodiment of the invention. In FIG. 2˜FIG. 4, similar components with FIG. 1A are given the same reference number and detailed description of the similar components will be omitted.

In an embodiment, as shown in FIG. 2, a trench LDMOS device is disposed on a substrate 100a. The substrate 100a for example is a silicon on insulator substrate. The silicon on insulator substrate includes an insulation layer 160 and a silicon layer 162.

In an embodiment, as shown in FIG. 3, a trench LDMOS device is disposed on a substrate 100a. The substrate 100a for example is a silicon on insulator substrate. The insulation layer having a silicon layer on top includes an insulation layer 160 and a silicon layer 162. The bottom of the trench 138 reaches the insulation layer 160 of the silicon on insulator substrate. The trench LDMOS device further includes a plurality of trench isolation structures 164. The trench isolation structure 164 is disposed at the trench 166 in the substrate 100a to isolate the first area 104 and the second area 106. Each trench isolation structure 164 respectively includes a conductive layer 168 and a dielectric layer 170. A material of the conductive layer 168 includes doped silicon or the like. The dielectric layer 170 is disposed between the conductive layer 168 and the substrate 100a. A material of the dielectric layer 170 for example is silicon oxide. The bottom of the trench 166 reaches the insulation layer 160 of the silicon on insulator substrate. The trench isolation structure 164 and the trench gate structure (the trench gate 130 and the gate dielectric layer 132) for example are formed during the same process.

In an embodiment, as shown in FIG. 4, the trench LDMOS device is disposed on a substrate 100. An embedded layer 172 is disposed in the substrate 100. The embedded layer 172 has a first conductive type, and located below the well region 126. The trench LDMOS device further includes a plurality of trench isolation structures 174. The plurality of trench isolation structures 174 are disposed in the substrate 100, penetrating the embedded layer 172 to isolate the first area 104 and the second area 106. Each trench isolation structure 174 respectively includes an insulation layer 176 and a doped region 178. The doped region 178 is disposed at the bottom of the insulation layer 176.

In the trench LDMOS device of the invention, the trench gate 130 protrudes from the surface of the substrate 100, so the step height difference between the trench gate 130 and the gate 114 may be decreased, and openings respectively exposing a top portion of the trench gate 130 and a top portion of the gate 114 may be formed without changing the manufacturing conditions.

Also, a spacer 152 is disposed on the side wall of the portion of the trench gate 130 protruding from the surface of the substrate 100, therefore electrical connection of the trench gate 130 and the doped region due to metal silicide may be prevented.

In addition, the dielectric layer 132 of the trench LDMOS transistor 112 does not produce an electric field, therefore leakage current may be prevented.

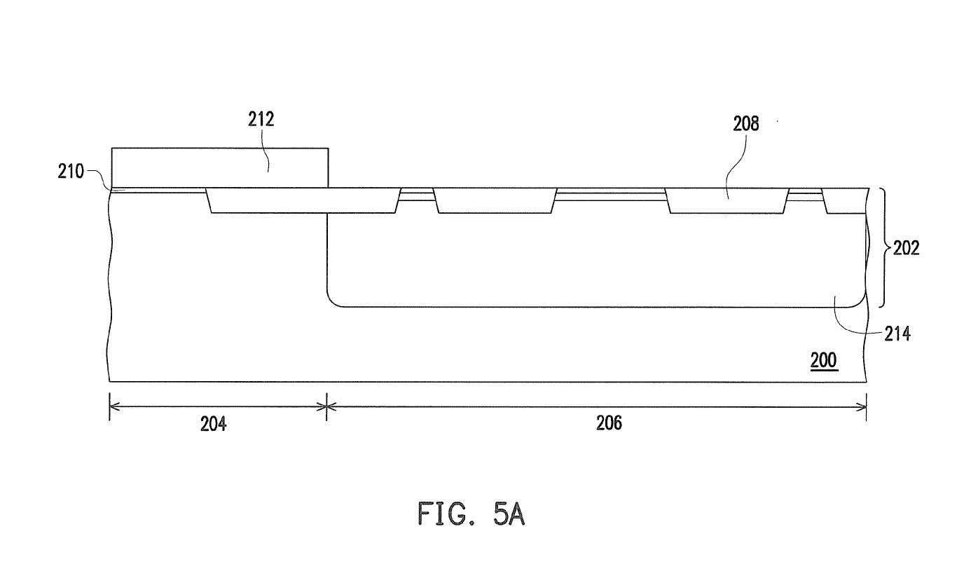

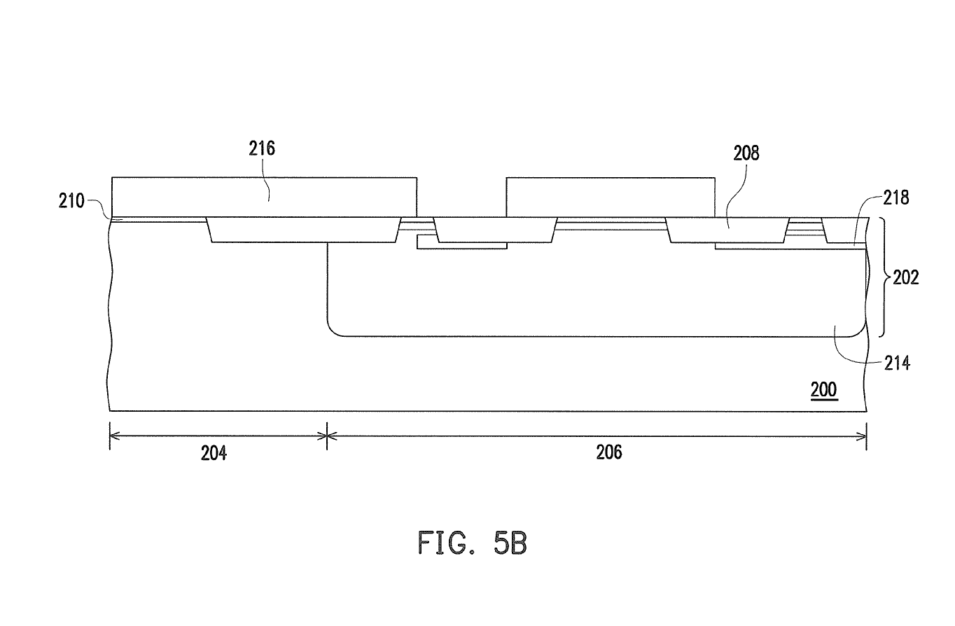

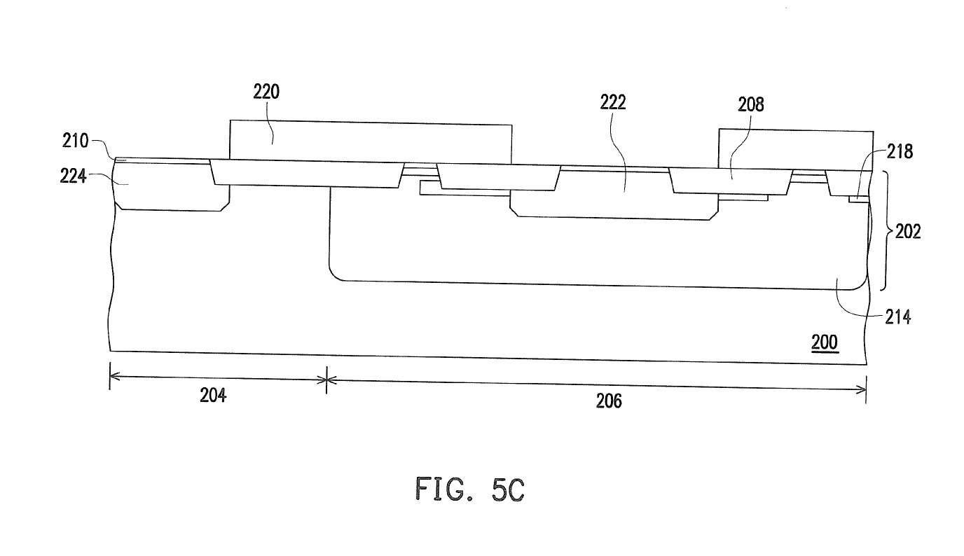

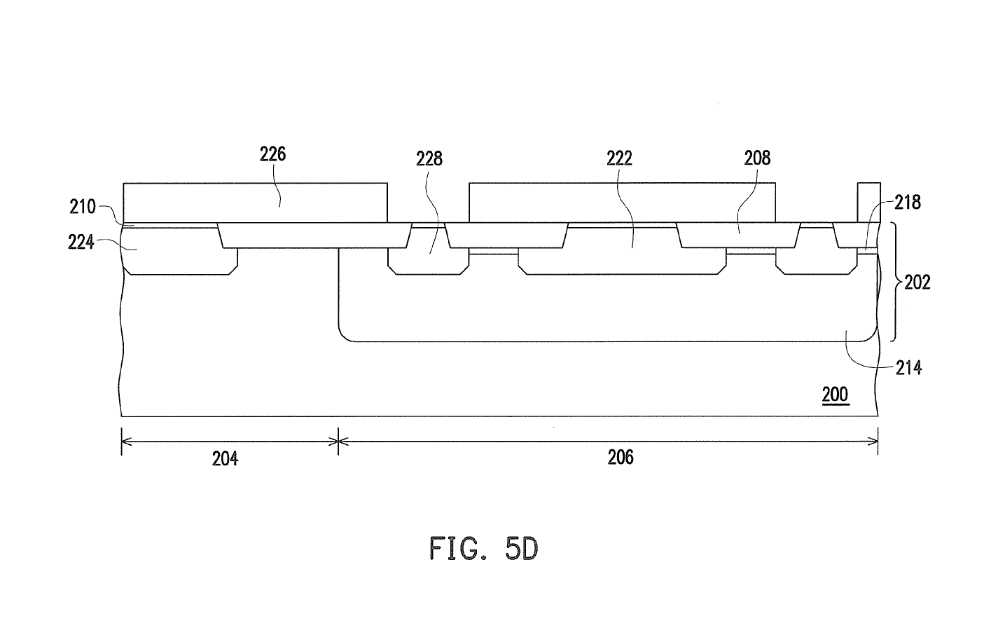

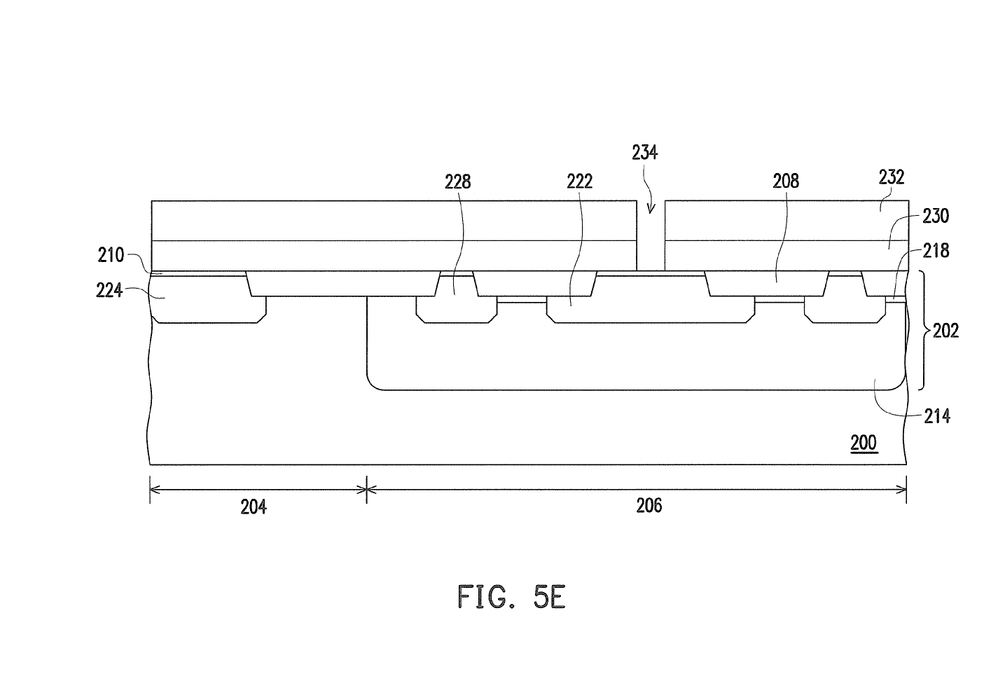

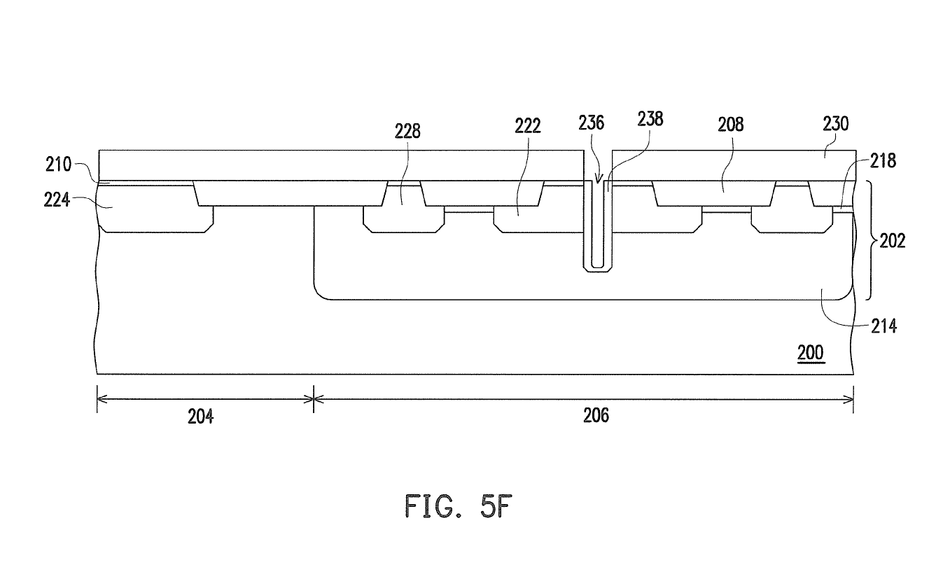

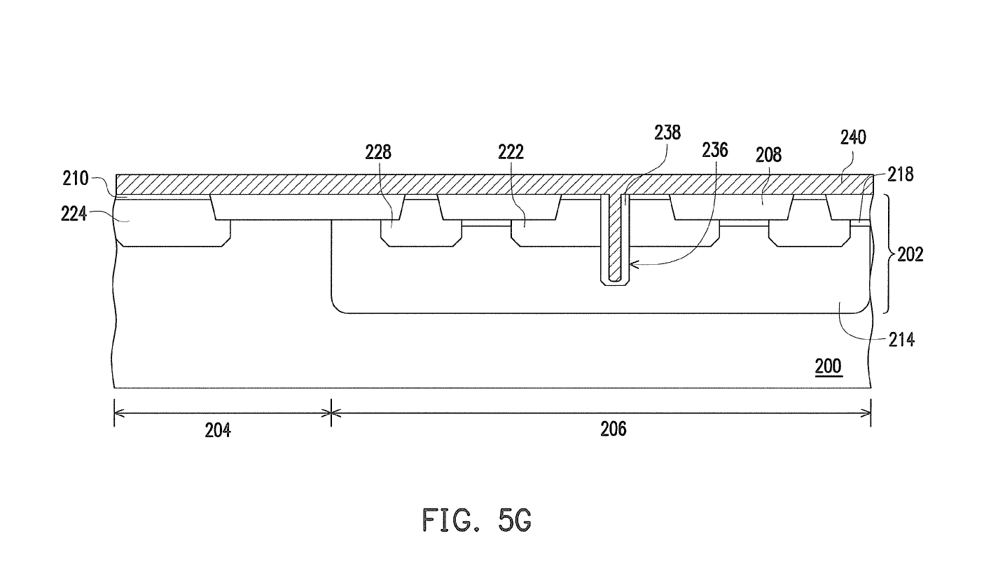

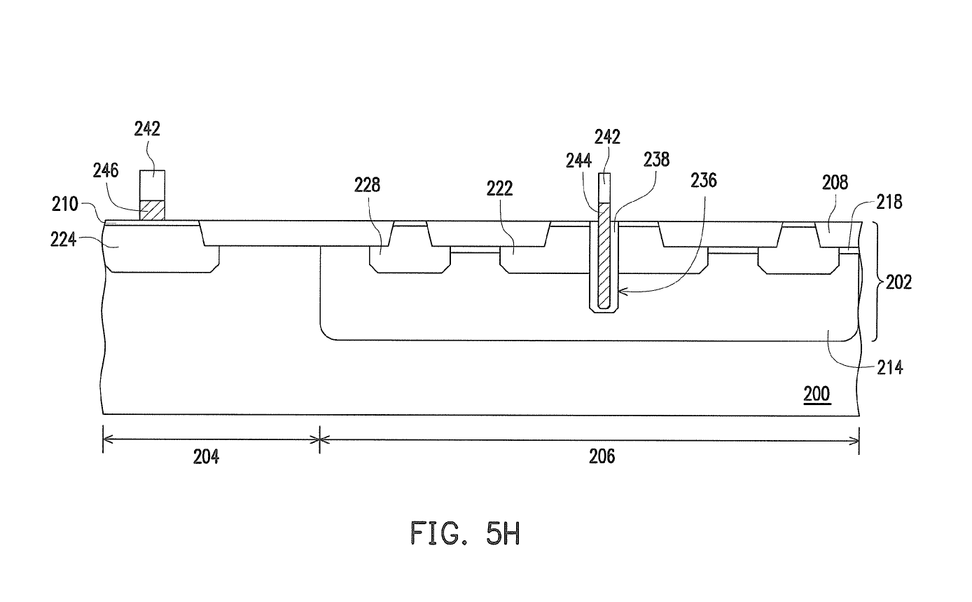

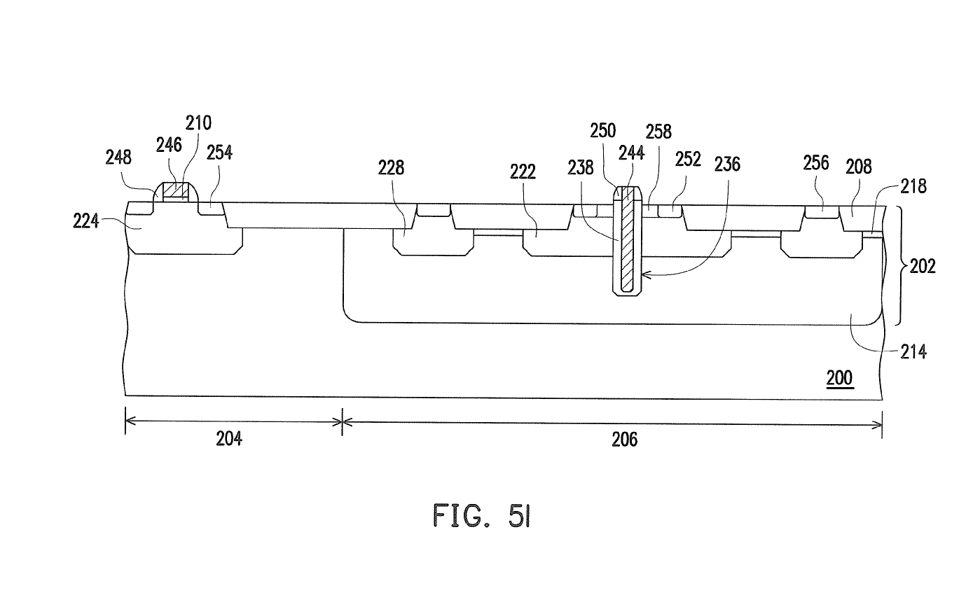

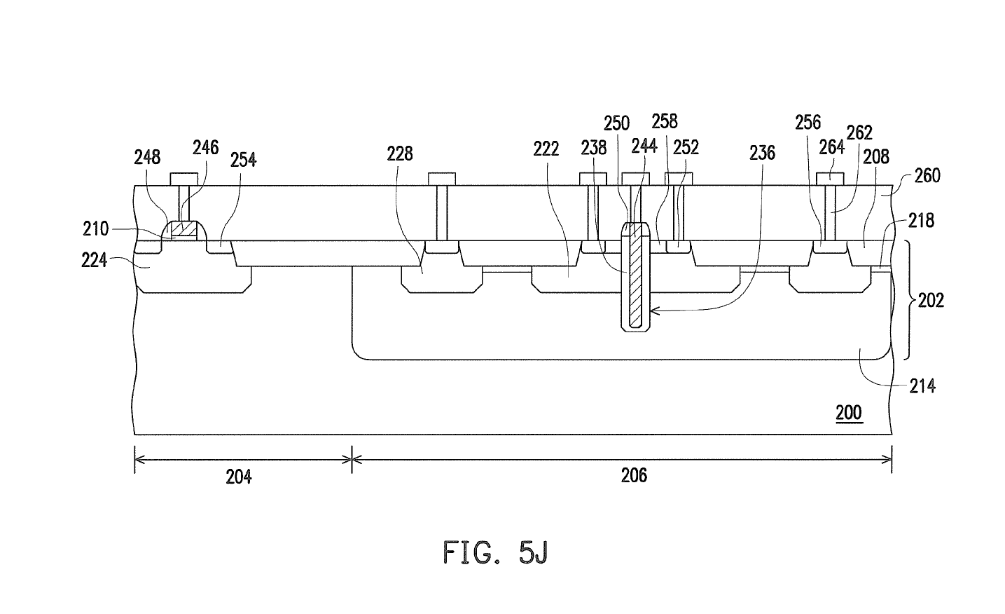

FIG. 5A˜FIG. 5J are cross-sectional views illustrating a manufacturing process of a trench LDMOS device according to an embodiment of the invention.

Referring to FIG. 5A, a substrate 200 is provided. The substrate 200 for example is a silicon substrate. The substrate 200 includes an epitaxial layer 202, and may be separated into a first area 204 and a second area 206.

Then, an element isolation structure 208 is formed in the substrate 200. The element isolation structure 208 for example is a shallow trench isolation (STI) structure. A formation method of the element isolation structure 208 includes the following steps. First, a patterned pad layer and a patterned mask layer are formed on the substrate, exposing a portion of the substrate. Then, the exposed portion of the substrate is removed to form a plurality of trenches in the substrate by using the patterned mask layer as a mask. Then, a material isolation layer is formed on the substrate to cover the patterned mask layer, and fill the trench. Next, the material isolation layer, the patterned mask layer and the patterned pad layer are removed, but the material isolation layer on the trench is left to form the isolation structure. Then, a dielectric layer 210 is formed on the substrate 200. A material of the dielectric layer 210 for example is silicon oxide. A forming method of the dielectric layer 210 for example is thermal oxidation or chemical vapour deposition.

A patterned photoresist layer 212 is formed on the substrate 200, exposing the second area 206. The patterned photoresist layer 212 is formed by, for example, performing exposure and developing. Then, a well region 214 is formed at the second area 206 of the substrate 200 by using the patterned photoresist layer 212 as a mask. The well region 214 is formed by, for example, performing an ion implantation process. The well region 214 may be a first conductive type well region or a second conductive type well region (namely an N-type well region or a P-type well region).

Referring to FIG. 5B, the patterned photoresist layer 212 is removed. The patterned photoresist layer 212 is removed by, for example, performing wet photoresist stripping, ashing or the like. Another patterned photoresist layer 216 is formed on the substrate 200, exposing the desired area to form a surface field reducing diffusion layer 218. The patterned photoresist layer 216 for example is formed through exposure and developing. A surface field reducing diffusion layer 218 is formed in the substrate 200 by using the patterned photoresist layer 216 as a mask. The surface field reducing diffusion layer 218 is formed by, for example, performing an ion implantation process. The surface field reducing diffusion layer 218 may be a first conductive type doped region.

Referring to FIG. 5C, the patterned photoresist layer 216 is removed. The patterned photoresist layer 216 is removed by, for example, performing wet photoresist stripping, ashing or the like. Another patterned photoresist layer 220 is formed on the substrate 200, exposing the desired area to form a well region of the first conductive type. The patterned photoresist layer 220 for example is formed through exposure and developing. A well region 222 is formed in the second area 206 of the substrate 200, and a well region 224 is formed at the first area 204 of the substrate 200 by using the patterned photoresist layer 220 as a mask. The well region 222 and the well region 224 are formed by for example ion implantation.

Referring to FIG. 5D, the patterned photoresist layer 220 is removed. The patterned photoresist layer 220 is removed by, for example, performing wet photoresist stripping, ashing or the like. Another patterned photoresist layer 226 is formed on the substrate 200, exposing the desired area to form a second conductive type well region. The patterned photoresist layer 226, for example, is formed through exposure and developing. A well region 228 is formed at the second area 206 of the substrate by using the patterned photoresist layer 226 as a mask. The well region 228 is formed by, for example, performing an ion implantation process.

Referring to FIG. 5E, the patterned photoresist layer 226 is removed. The patterned photoresist layer 226 is removed by, for example, performing wet photoresist stripping, ashing or the like. A mask layer is formed on the substrate 200. A material of the mask layer, for example, is silicon nitride. The mask layer is formed by, for example, performing a chemical vapor deposition (CVD) process. Then a patterned photoresist layer 232 is formed on the mask layer, exposing the desired area to form a trench. The patterned photoresist layer 232, for example, is formed through exposure and developing. A portion of the mask layer is removed to form the patterned mask layer 230 having an opening 234 by using the patterned photoresist layer 232 as a mask.

Referring to FIG. 5F, the patterned photoresist layer 232 is removed. The patterned photoresist layer 232 is removed by, for example, performing wet photoresist stripping, ashing or the like. Then, a portion of the substrate 200 is removed to form the trench 236 by using the patterned mask layer 230 as a mask. Next, a gate dielectric layer 238 is formed on the surface of the trench 236. A material of the gate dielectric layer 238 is, for example, silicon oxide. The gate dielectric layer 238 is formed by, for example, performing a thermal oxidation or a chemical vapor deposition process.

Referring to FIG. 5G, the patterned mask layer 230 is removed. The patterned mask layer 230 is removed by, for example, pertaining wet etching or dry etching. Then, a conductive layer 240 is formed on the substrate 200, the conductive layer 240 maintains a certain thickness on the substrate 200, and fills the trench 236. A material of the conductive layer 240 for example is doped polysilicon. The conductive layer 240 is formed by for example, performing a chemical vapor deposition process to form a non-doped polysilicon layer, and then performing an ion implantation step; or performing a chemical vapor deposition process with in-situ dopant implantation. Besides, when forming the conductive layer 240, a planarization process may be further performed after the deposition process. The planarization process is, for example, chemical mechanical polishing (CMP).

Referring to FIG. 5H, another patterned photoresist layer 242 is formed on the substrate 200, covering the desired area to form a gate. The patterned photoresist layer 242 for example is formed through exposure and developing. A portion of the conductive layer 240 is removed to form the gate 246 at the first area 204 of the substrate 200, and to form a trench gate 244 at the second area 206 of the substrate 200 by using the patterned photoresist layer 242 as a mask. The gate dielectric layer 238 and the trench gate 244 make up the trench gate structure.

Referring to FIG. 5I, a spacer 250 is formed on a side wall of the portion of the trench gate 244 protruding from the surface of the substrate 200, and a spacer 248 is formed on the side wall of the gate 246. The spacer 248 and the spacer 250 are formed by, for example, forming an interlayer insulation layer (not shown) on the substrate 200 first, and then removing a portion of the insulation layer using anisotropic etching. A material of the spacer 248 and the spacer 250 is, for example, silicon oxide, silicon nitride or silicon oxynitride.

A doped region 252 is formed on the surface of the substrate at two sides of the trench gate structure. Then a doped region 258 is formed on the surface of the substrate 200 between the trench gate structure and the doped region 252, and a doped region 254 (source/drain region) is formed at two sides of the gate 246 in the substrate 200, and a doped region 256 is formed on the surface of the well region 228. The doped region 252, the doped region 254 (source/drain region) and the doped region 256 are formed by, for example, performing an ion implantation process.

Referring to FIG. 5J, next, an interlayer insulation layer 260 is formed on the substrate 200. A material of the interlayer insulation layer 260 for example is phosphorus silicate glass, boron phosphor silicate glass or the like. The interlayer insulation layer 260 is formed by, for example, performing a chemical vapour deposition. Then a portion of the interlayer insulation layer 260 is removed to form a plurality of openings. A portion of the interlayer insulation layer 260 is removed by performing a photolithography process. Next, plugs 262 are formed in the openings, the plugs 262 are formed by, for example, first forming a conductive material layer to fill the opening on the substrate 200, then removing a portion of the conductive material layer until the interlayer insulation layer 260 is exposed by using chemical mechanical polishing. Then, a plurality of conductive wires 264 are formed on the interlayer insulation layer 260. The conductive wires 264 are formed by, for example, first forming a conductive material layer on the substrate 200, then removing a portion of the conductive material layer using a photolithography process. The subsequent steps of the manufacturing process to complete a trench LDMOS device is conventional knowledge to a person skilled in the art and will not be repeated here.

In the manufacturing method of the above trench LDMOS device, the conductive layer 240 maintains a certain thickness on the substrate 200 such that the trench gate 244 formed by the conductive layer 240 protrude from the surface of the substrate 200, and the step height of the portion of the trench gate 244 protruding from the surface of the substrate 200 may be determined by the thickness of the conductive layer 240.

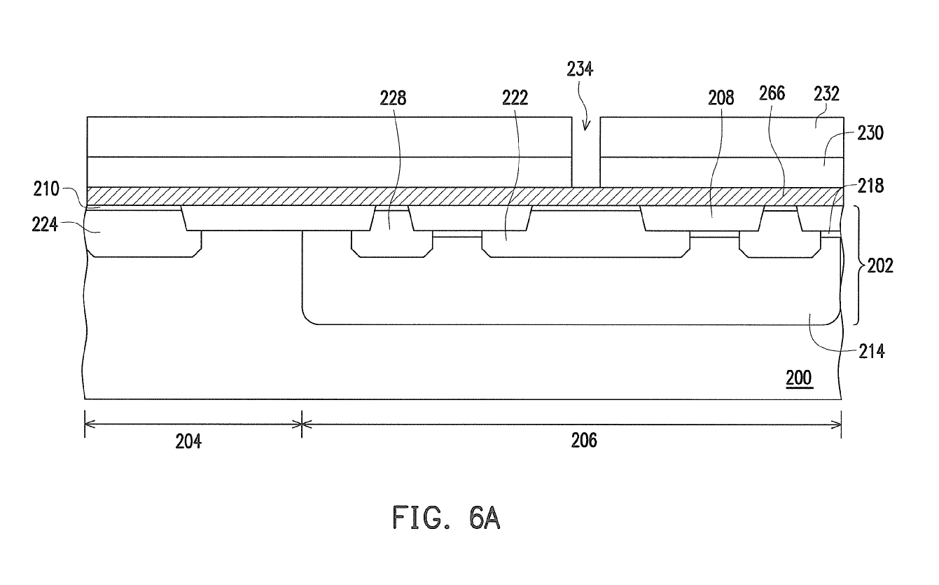

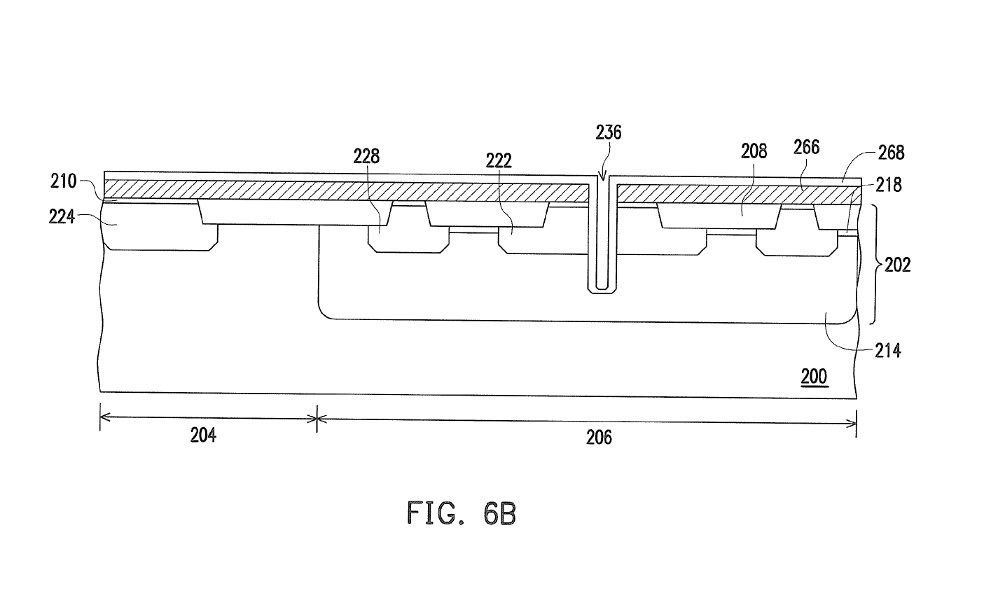

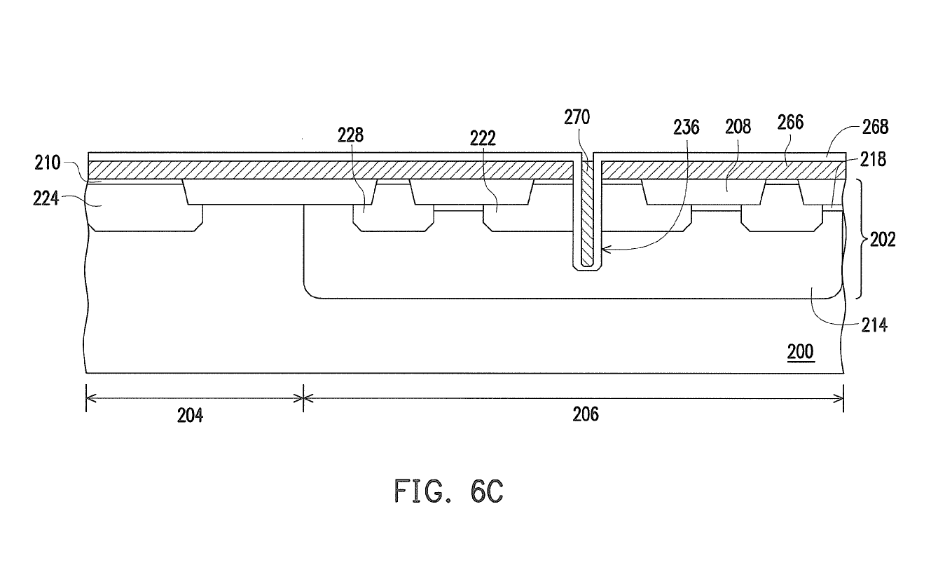

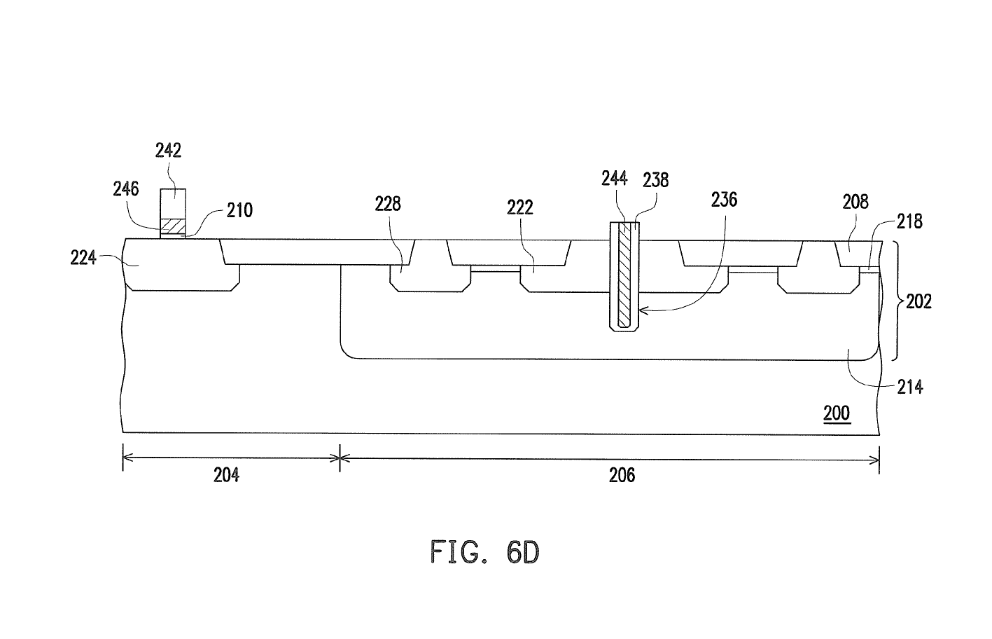

FIG. 6A˜FIG. 6D are cross-sectional views illustrating a manufacturing process of a trench LDMOS device according to another embodiment of the invention. FIG. 6A˜FIG. 6D are cross-sectional views illustrating a manufacturing process of a trench LDMOS device continued from the above FIG. 5D. In FIG. 6A˜FIG. 6D, similar components with FIG. 5A˜FIG. 5J are given same references numbers, and detailed description of similar components will be omitted.

Referring to FIG. 6A, the patterned photoresist layer 226 is removed. The patterned photoresist layer 226 is removed by, for example, performing wet photoresist stripping, ashing or the like. A conductive layer 266 is formed on the substrate 200. A material of the conductive layer 266 is, for example, doped polysilicon. The conductive layer 266 is formed by, for example, performing a chemical vapor deposition process to form a non-doped polysilicon layer, then performing an ion implantation step; or performing a chemical vapor deposition process with in-situ dopant implantation.

A mask layer is formed on the conductive layer 266. A material of the conductive layer is, for example, silicon nitride. The mask layer is formed by, for example, performing a chemical vapor deposition process. Then, a patterned photoresist layer 232 is formed on the mask layer, exposing the desired area to form a trench. The patterned photoresist layer 232 for example is formed through exposure and developing. A portion of the mask layer is removed to form a patterned mask layer 230 having an opening 234 by using the patterned photoresist layer 232 as a mask.

Referring to FIG. 6B, the patterned photoresist layer 232 is removed. The patterned photoresist layer 232 is removed by, for example, performing wet photoresist stripping, ashing or the like. Then, a portion of the conductive layer 266 and a portion of the substrate 200 is removed to form the trench 236 by using the patterned mask layer 230 as a mask. Next the patterned mask layer 230 is removed. The patterned mask layer 230 is removed by, for example, performing wet etching or dry etching. Then, a dielectric layer 268 is formed on the surface of the conductive layer 266 and the trench 236. A material of the dielectric layer 268 for example is silicon oxide. The dielectric layer 268 is formed by, for example, performing a thermal oxidation or a chemical vapor deposition process.

Referring to FIG. 6C, a conductive layer 270 is filled in the trench 236. The conductive layer 270 is formed by, for example, first depositing a conductive material layer on the substrate 200, then performing a planarization process until the surface of the dielectric layer 268 is exposed. The planarization process is, for example, a dry etching or a chemical mechanical polishing process. A material for the conductive material layer (conductive layer 270) is, for example, doped polysilicon. The conductive material layer is formed by, for example, performing a chemical vapor deposition process to form a non-doped polysilicon layer, and then performing an ion implantation step; or performing a chemical vapor deposition process with in-situ dopant implantation.

Referring to FIG. 6D, the dielectric layer 268 on the surface of the conductive layer 266 is removed, the gate dielectric layer 238 located in the trench 236 is left. The dielectric layer 268 is removed by, for example, performing wet etching. Another patterned photoresist layer 242 is formed on the substrate 200, covering the desired area to form a gate. The patterned photoresist layer 242 for example is formed through exposure and developing. A portion of the conductive layer 266 is removed to form the gate 246 at the first area 204 of the substrate 200 by using the patterned photoresist layer 242 as a mask, and the trench gate 244 is also formed at the second area 206 of the substrate 200 without using the patterned photoresist layer 242 as a mask. The gate dielectric layer 238 and the trench gate 244 make up the trench gate structure. The subsequent steps of the manufacturing process are as shown in the above FIG. 5I and FIG. 5J and will not be repeated here.

In the manufacturing method of the above trench LDMOS device, the conductive layer 270 is formed after forming the conductive layer 266 on the substrate 200. Therefore the trench gate 244 is formed to protrude from the surface of the substrate 200, and the step height of the portion of the trench gate 244 protruding from the surface of the substrate 200 may be determined by the thickness of the conductive layer 266.

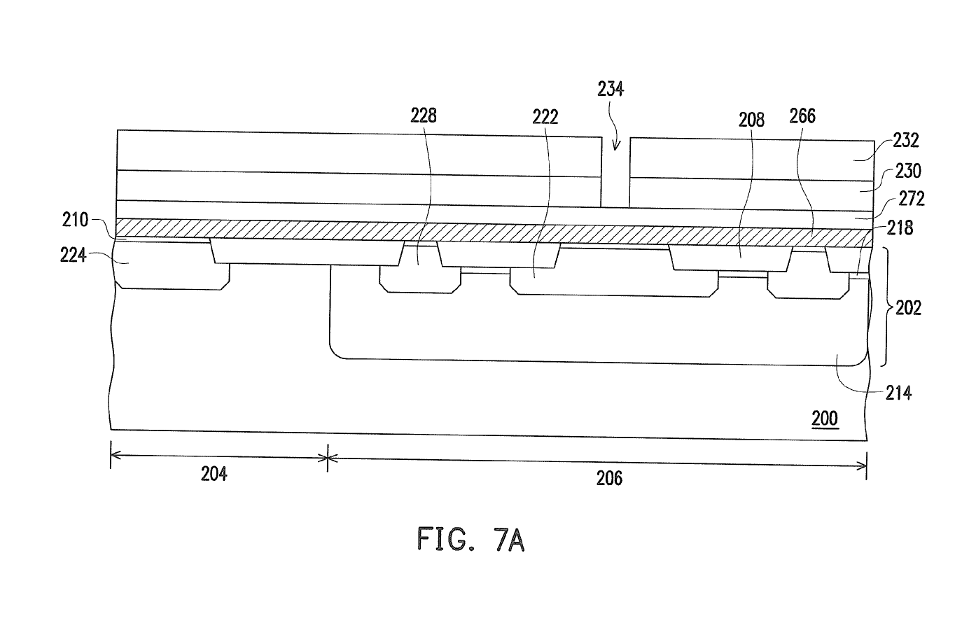

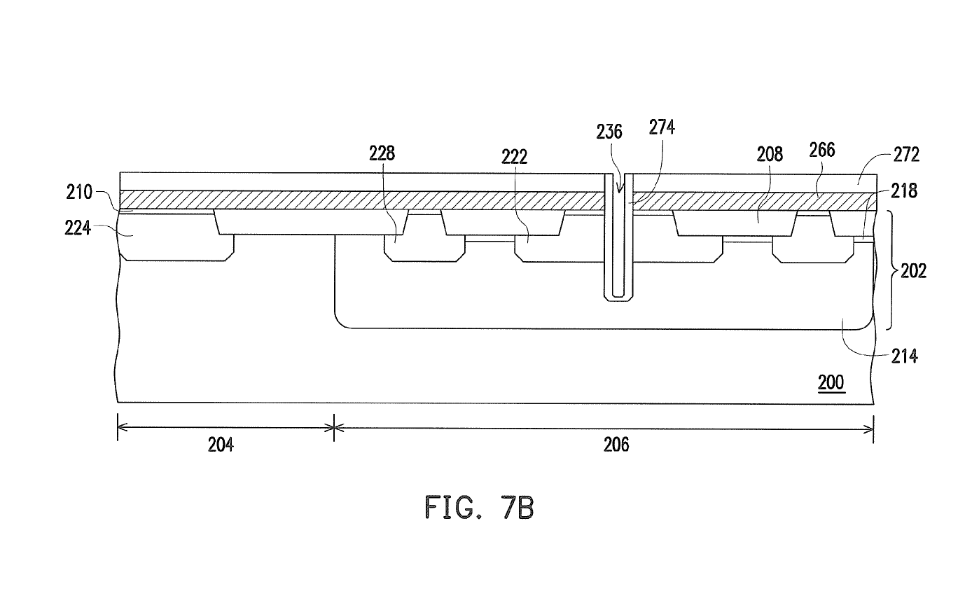

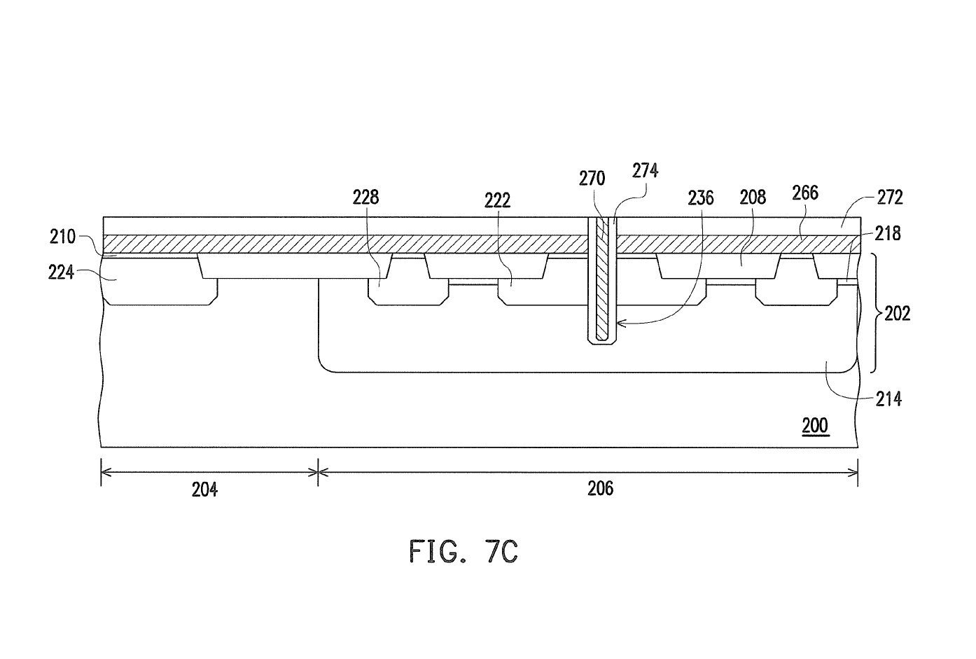

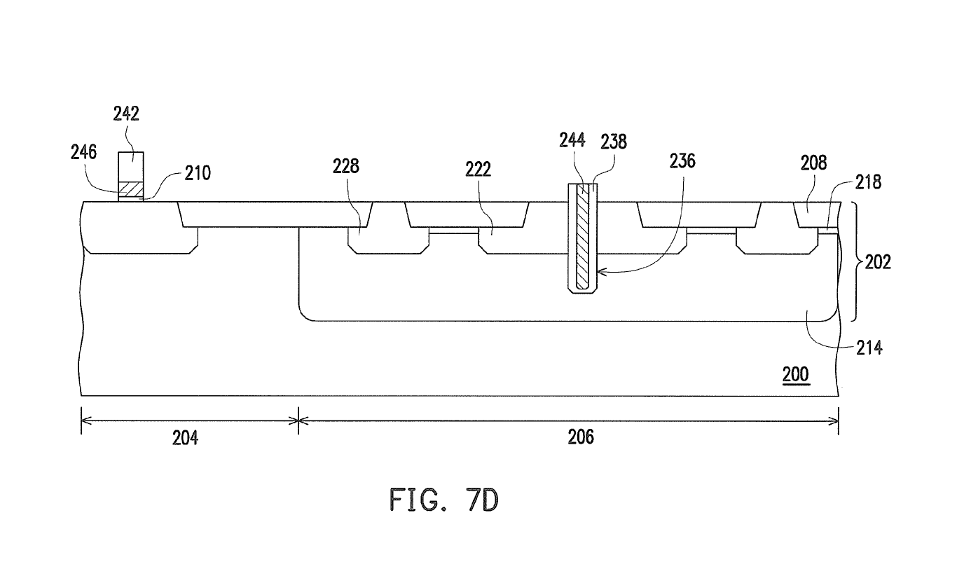

FIG. 7A˜FIG. 7D are cross-sectional views illustrating a manufacturing process of a trench LDMOS device according to another embodiment of the invention. FIG. 7A˜FIG. 7D are cross-sectional views illustrating a manufacturing process of a trench LDMOS device continued from the above FIG. 5D. In FIG. 7A˜FIG. 7D, similar components with FIG. 5A˜FIG. 5J are given same references numbers, and detailed description of similar components will be omitted.

Referring to FIG. 7A, the patterned photoresist layer 226 is removed. The patterned photoresist layer 266 is removed by, for example, performing wet photoresist stripping, ashing or the like. A conductive layer 266 is formed on the substrate 200. A material of the conductive layer 266 for example is doped polysilicon. The conductive layer 266 is formed by, for example, performing a chemical vapor deposition process to form a non-doped polysilicon layer, then performing an ion implantation step; or performing a chemical vapor deposition process with in-situ dopant implantation. A sacrificial layer 272 is formed on the conductive layer 266. A material of the sacrificial layer 272 for example is silicon oxide. The sacrificial layer 272 is formed by, for example, performing a chemical vapor deposition process.

A mask layer is formed on the conductive layer 266. A material of the mask layer for example is silicon nitride. The mask layer is formed by, for example, performing a chemical vapor deposition process. Then a patterned photoresist layer 232 is formed on the mask layer, exposing the desired area to form a trench. The patterned photoresist layer 232 for example is formed through exposure and developing. A portion of the mask layer is removed to form the patterned mask layer 230 having an opening 234 by using the patterned photoresist layer 232 as a mask.

Referring to FIG. 7B, the patterned photoresist layer 232 is removed. The patterned photoresist layer 232 is removed by, for example, performing wet photoresist stripping, aching or the like. Then, a portion of the sacrificial layer 272, a portion of the conductive layer 266 and a portion of the substrate 200 are removed to form the trench 236 by using the patterned mask layer 230 as a mask. Then, the patterned mask layer 230 is removed. The patterned mask layer 230 is removed by, for example, performing wet etching or dry etching. Next, a dielectric layer 274 is formed on the surface of the trench 236. A material of the dielectric layer 274 for example is silicon oxide. The dielectric layer 274 is formed by, for example, performing a thermal oxidation or a chemical vapor deposition process.

Referring to FIG. 7C, a conductive layer 270 is filled in the trench 236. The conductive layer 270 is formed by, for example, first depositing a conductive material layer on the substrate 200, then performing a planarization process until the surface of the sacrificial layer 272 is exposed. The planarization process is, for example, dry etching or chemical mechanical polishing. A material of the conductive material layer (conductive layer 270) is, for example, doped polysilicon. The conductive material layer is formed by, for example, performing a chemical vapor deposition process to form a non-doped polysilicon layer, and then performing an ion implantation step; or performing a chemical vapor deposition process with in-situ dopant implantation.

Referring to FIG. 7D, the sacrificial layer 272 on the surface of the conductive layer 266 is removed, the gate dielectric layer 238 located in the trench 236 is left. The sacrificial layer 272 is removed by, for example, performing wet etching. Another patterned photoresist layer 242 is formed on the substrate 200, covering the desired area for forming a gate. The patterned photoresist layer 242 for example is formed through exposure and developing. A portion of the conductive layer 266 is removed to form the gate 246 at the first area 204 of the substrate 200 by using the patterned photoresist layer 242 as a mask, and to form the trench gate 244 at the second area 206 of the substrate 200 without using the patterned photoresist layer 242 as a mask. The gate dielectric layer 238 and the trench gate 244 make up the trench gate structure. The subsequent steps of the manufacturing process are as shown in the above FIG. 5I and FIG. 5J and will not be repeated here.

In the manufacturing method of the above trench LDMOS device, the conductive layer 270 is formed after the conductive layer 266 and the sacrificial layer 212 are formed on the substrate 200. Therefore the trench gate 244 is formed to protrude from the surface of the substrate 200, and the step height of the portion of the trench gate 244 protruding from the surface of the substrate 200 may be determined by the thickness of the conductive layer 266 and the sacrificial layer 212.

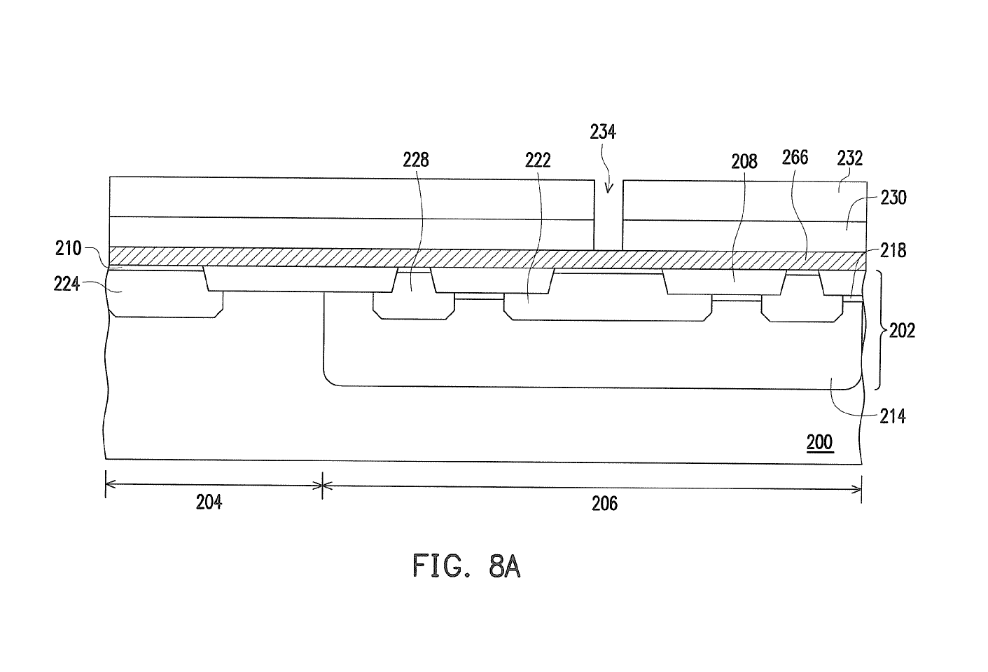

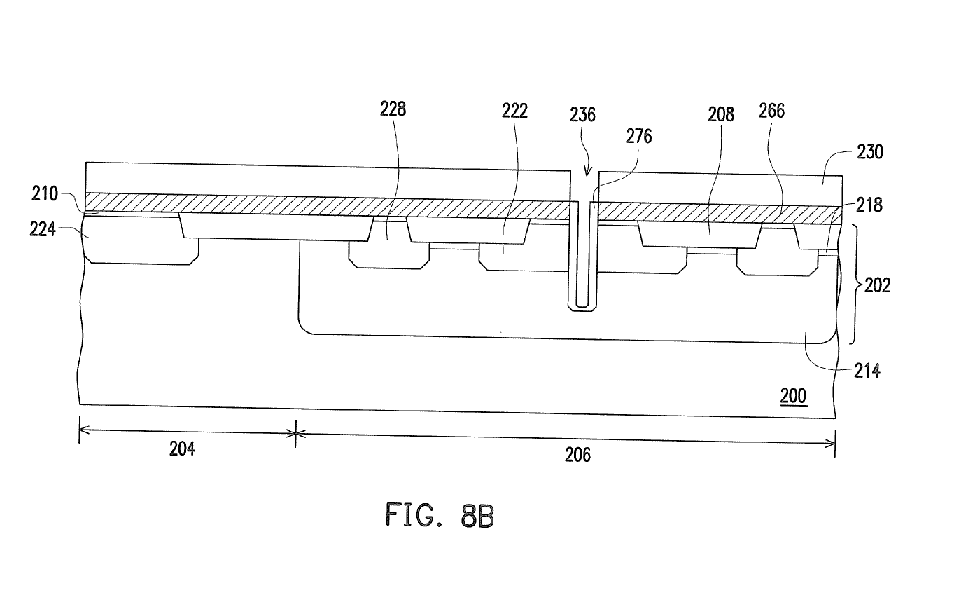

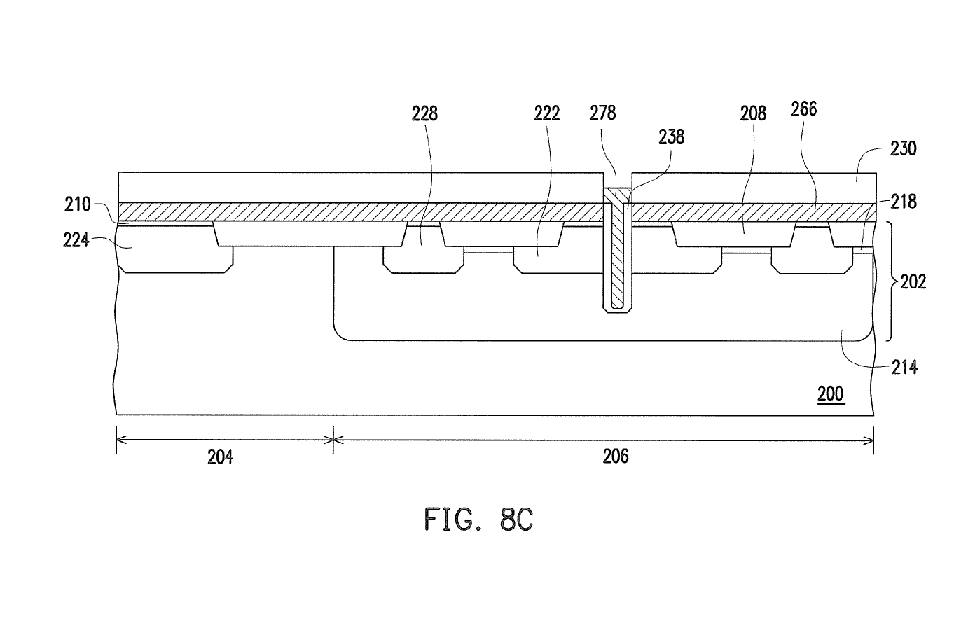

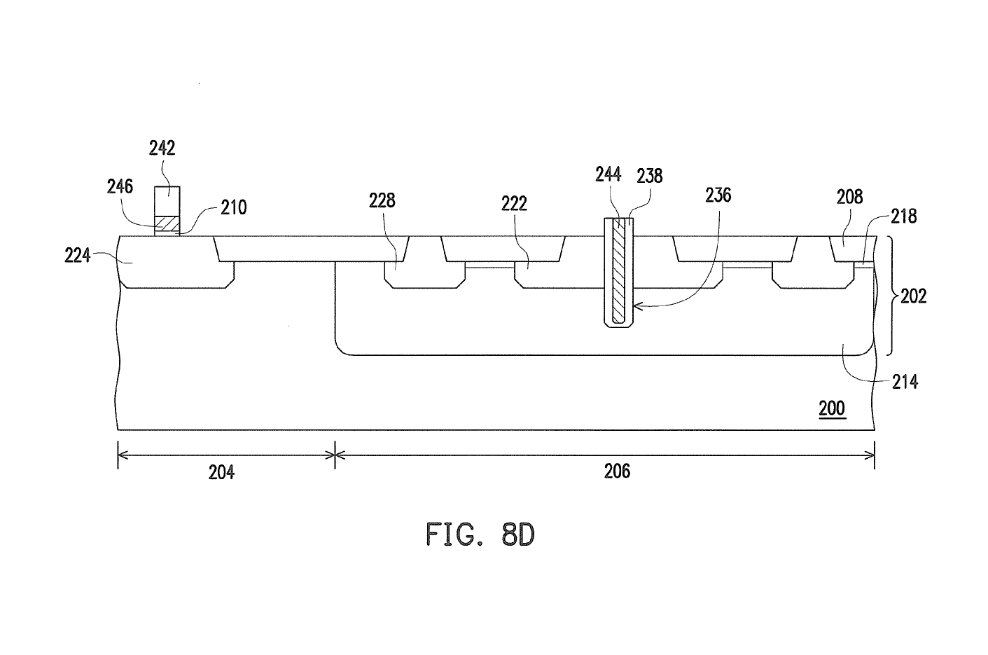

FIG. 8A˜FIG. 8D are cross-sectional views illustrating a manufacturing process of a trench LDMOS device according to another embodiment of the invention. FIG. 8A˜FIG. 8D are cross-sectional views illustrating a manufacturing process of a trench LDMOS device continued from the above FIG. 5D. In FIG. 8A˜FIG. 8D, similar components with FIG. 5A˜FIG. 5J are given same references numbers, and detailed description of similar components will be omitted.

Referring to FIG. 8A, the patterned photoresist layer 226 is removed. The patterned photoresist layer 226 is removed by, for example, performing wet photoresist stripping, ashing or the like. A conductive layer 266 is formed on the substrate 200. A material of the conductive layer 266 for example is doped polysilicon. The conductive layer 266 is aimed by, for example, performing a chemical vapour deposition process to form a non-doped polysilicon layer, and then performing an ion implantation step; or performing a chemical vapor deposition process with in-situ dopant implantation.

A mask layer is formed on the conductive layer 266. A material of the mask layer for example is silicon nitride. The mask layer is formed by, for example, performing a chemical vapor deposition process. Then a patterned photoresist layer 232 is formed on the mask layer, exposing the desired area to form a trench. The patterned photoresist layer 232 for example is formed through exposure and developing. A portion of the mask is removed to form a patterned mask layer 230 having an opening 234 by using the patterned photoresist layer 232 as a mask.

Referring to FIG. 8B, the patterned photoresist layer 232 is removed. The patterned photoresist layer 232 is removed by, for example, performing wet photoresist stripping, ashing or the like. Then a portion of the conductive layer 266 and a portion of the substrate 200 are removed to form the trench 236 by using the patterned mask layer 230 as a mask. Next a dielectric layer 276 is formed on the surface of the trench 236. A material of the dielectric layer 276 for example is silicon oxide. The dielectric layer 276 is formed by, for example, performing a thermal oxidation or a chemical vapor deposition process.

Referring to FIG. 8C, a conductive layer 278 is filled in the trench 236. The conductive layer 278 is formed by, for example, depositing a conductive material layer on the substrate 200, and then performing a planarization process until the surface of the patterned mask layer 230 is exposed. The planarization process is, for example, dry etching or chemical mechanical polishing. A material of the conductive material layer (conductive layer 278) for example is doped polysilicon. The conductive material layer is formed by, for example, performing a chemical vapor deposition process to form a non-doped polysilicon layer, then performing an ion implantation step; or performing a chemical vapor deposition process with in-situ dopant implantation.

Referring to FIG. 8D, the patterned mask layer 230 is removed. The patterned mask layer 230 is removed by, for example, performing wet etching or dry etching. Another patterned photoresist layer 242 is formed on the substrate 200, covering the desired area for forming a gate. The patterned photoresist layer 242 is formed, for example, through exposure and developing. A portion of the conductive layer 266 is removed to form the gate 246 at the first area 204 of the substrate 200 by using the patterned photoresist layer 242 as a mask, and to form the trench gate 244 at the second area 206 of the substrate 200 without using the patterned photoresist layer 242 as a mask. The gate dielectric layer 238 and the trench gate 244 make up the trench gate structure. The subsequent steps of the manufacturing process are as shown in the above FIG. 5I and FIG. 5J and will not be repeated here.

In the manufacturing method of the above trench LDMOS device, after the conductive layer 266 and the patterned mask layer 230 are formed on the substrate 200, first the conductive layer 278 is formed, then the patterned mask layer 230 is removed. Therefore the trench gate 244 formed protrudes from the surface of the substrate 200, and the step height of the portion of the trench gate 244 protruding from the surface of the substrate 200 may be determined by the thickness of the conductive layer 266.

In the manufacturing method of the trench LDMOS device of the invention, the trench gate 244 and the gate 246 may be formed in the same process. Therefore the manufacturing process may be simplified. In addition, the trench gate 244 protrudes from the surface of the substrate 200, so a step height difference of the trench gate 244 and the gate 246 may be decreased, and openings respectively exposing a top portion of the trench gate 244 and a top portion of the gate 246 may be formed in the interlayer insulation layer 260 without changing the manufacturing conditions.

In addition, a spacer 250 is disposed on a side wall of the portion of the trench gate 244 protruding from the surface of the substrate 200, therefore electrical connection of the trench gate 244 and the doped region 252 due to metal silicide may be prevented. In addition, the gate dielectric layer 238 of the trench LDMOS transistor does not produce an electric field, therefore leakage current may be prevented.

In summary, the trench LDMOS device and the manufacturing method thereof of the invention, has a trench gate protruding from the surface of the substrate, so the step height difference of the trench gate and the gate may be decreased, and openings respectively exposing a top portion of the trench gate and a top portion of the gate may be formed in the interlayer insulation layer without changing the manufacturing conditions.

Furthermore, a spacer is disposed on the side wall of the portion of the trench gate protruding from the surface of the substrate, therefore electrical connection of the trench gate and the doped region due to metal silicide may be prevented. In addition, the gate dielectric layer of the trench LDMOS transistor does not produce an electric field, therefore leakage current may be prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A trench LDMOS device, disposed on a substrate, comprising:
a transistor, disposed on a first area of the substrate, the transistor comprising a gate; and
a trench LDMOS transistor, disposed on a second area of the substrate, comprising:
a first well region, disposed in the second area of the substrate;
a second well region, having a first conductivity type, disposed in the first well region;
a trench gate, disposed in a trench of the substrate, wherein the trench gate protrudes from a surface of the substrate, and the trench is located in the second well region;
a gate dielectric layer, disposed between the trench gate and the substrate;
a first doped region, having the first conductivity type, disposed in the substrate at two sides of the trench gate; and
a second doped region, having a second conductivity type, disposed in the substrate between the trench gate and the first doped region.

2. The trench LDMOS device as claimed in claim 1, wherein a step height of a portion of the trench gate protruding from the surface of the substrate is lower than a step height of the gate.

3. The trench LDMOS device as claimed in claim 1, wherein a step height of a portion of the trench gate protruding from the surface of the substrate is higher than a step height of the gate.

4. The trench LDMOS device as claimed in claim 1, further comprising a spacer, disposed on a side wall of a portion of the trench gate protruding from the surface of the substrate.

5. The trench LDMOS device as claimed in claim 1, further comprising:
a third well region, having the second conductivity type, disposed in the first well region;
a third doped region, having the second conductivity type, disposed in the third well region; and
an element isolation structure, disposed in the substrate to isolate the second well region and the third well region.

6. The trench LDMOS device as claimed in claim 1, wherein a depth of the trench is greater than a depth of a junction at a bottom of the second well region.

7. The trench LDMOS device as claimed in claim 1, wherein the substrate is a silicon on insulator substrate.

8. The trench LDMOS device as claimed in claim 7, wherein a bottom of the trench reaches an insulating layer of the silicon on insulator substrate.

9. The trench LDMOS device as claimed in claim 8, further comprising:
a plurality of trench isolation structures, disposed in the substrate to isolate the first area and the second area, wherein each of the trench isolation structures respectively comprises a conductive layer and a dielectric layer disposed between the conductive layer and the substrate.

10. The LDMOS device as claimed in claim 1, further comprising:
an embedded layer, having the first conductive type, disposed in the substrate, and located below the first well region; and
a plurality of trench isolation structures, disposed in the substrate to perforate the embedded layer and isolate the first area and the second area, wherein each of the trench isolation structures respectively comprises an insulation layer and a fourth doped region disposed at a bottom of the insulating layer.

11. The trench LDMOS device as claimed in claim 5, further comprising a fifth doped region, having the second conductivity, connected two third doped regions respectively disposed in the third well regions on two sides of the second well region.

12. The trench LDMOS device as claimed in claim 11, wherein the first well region alternately comprises the first conductivity and the second conductivity along an extension direction of the trench gate.

13. The trench LDMOS device as claimed in claim 1, further comprising a sixth doped region, having the first conductivity, connected two first doped regions respectively disposed in two adjacent second well regions.

14. A manufacturing method of a trench LDMOS device, comprising:
providing a substrate, the substrate comprising a first area and a second area;
forming a first well region at the second area of the substrate;
forming a second well region in the first well region;
forming a trench gate structure at the second area of the substrate, the trench gate structure protruding from a surface of the substrate, and located in the second well region, wherein the trench gate structure comprises a trench gate and a gate dielectric layer disposed between the trench gate and the substrate;
forming a first doped region on the surface of the substrate at two sides of the trench gate structure; and
forming a second doped region on the surface of the substrate between the trench gate structure and the first doped region.

15. The manufacturing method of the trench LDMOS device as claimed in claim 14, further comprising forming a spacer on a side wall of a portion of the trench gate structure protruding from the surface of the substrate.

16. The manufacturing method of the trench LDMOS device as claimed in claim 14, wherein the step of forming the trench gate structure at the second area of the substrate comprises:
forming a patterned mask layer on the substrate;
removing a portion of the substrate to form a trench in the substrate by using the patterned mask layer as a mask;
forming the gate dielectric layer on the surface of the trench;
removing the patterned mask layer;
forming a conductive layer filling the trench on the substrate; and
patterning the conductive layer to form the trench gate.

17. The manufacturing method of the trench LDMOS device as claimed in claim 16, wherein the step of patterning the conductive layer further comprises:
forming a gate at the first area of the substrate.

18. The manufacturing method of the trench LDMOS device as claimed in claim 14, wherein the step of forming the trench gate structure at the second area of the substrate comprises:
forming a first conductive layer on the substrate;
forming a patterned mask layer on the first conductive layer;
removing a portion of the first conductive layer and a portion of the substrate to form a trench in the substrate by using the patterned mask layer as a mask;
removing the patterned mask layer;
forming a dielectric layer on the surface of the first conductive layer and the trench;
forming a second conductive layer filling the trench on the substrate;
removing the second conductive layer to expose the dielectric layer;
removing a portion of the dielectric layer to form the gate dielectric layer; and
patterning the first conductive layer to form the trench gate.

19. The manufacturing method of the trench LDMOS device as claimed in claim 18, wherein the step of patterning the first conductive layer further comprises:
forming a gate at the first area of the substrate.

20. The manufacturing method of the trench LDMOS device as claimed in claim 18, wherein the step of removing the second conductive layer comprises performing a chemical mechanical polishing process.

21. The manufacturing method of the trench LDMOS device as claimed in claim 14, wherein the step of forming the trench gate structure at the second area of the substrate comprises:
forming a first conductive layer on the substrate;
forming a sacrificial layer on the first conductive layer;
forming a patterned mask layer on the sacrificial layer;
removing a portion of the sacrificial layer, a portion of the first conductive layer and a portion of the substrate to form a trench in the substrate by using the patterned mask layer as a mask;
removing the patterned mask layer;
forming the gate dielectric layer on the surface of the trench;
forming a second conductive layer filling the trench on the substrate;
removing the second conductive layer to expose the sacrificial layer;
removing the sacrificial layer; and
patterning the first conductive layer to form the trench gate.

22. The manufacturing method of the trench LDMOS device as claimed in claim 21, wherein the step of patterning the first conductive layer further comprises:
forming a gate at the first area of the substrate.

23. The manufacturing method of the trench LDMOS device as claimed in claim 21, wherein the step of removing the second conductive layer comprises performing a chemical mechanical polishing process.

24. The manufacturing method of the trench LDMOS device as claimed in claim 14, wherein the step of forming the trench gate structure at the second area of the substrate comprises:
forming a first conductive layer on the substrate;
forming a patterned mask layer on the first conductive layer;
removing a portion of the first conductive layer and a portion of the substrate to form a trench in the substrate by using the patterned mask layer as a mask;
forming the gate dielectric layer on the surface of the trench;
forming a second conductive layer filling the trench on the substrate;
removing the second conductive layer to expose the patterned mask layer;
removing the patterned mask layer; and
patterning the first conductive layer to form the trench gate.

25. The manufacturing method of the trench LDMOS device as claimed in claim 24, wherein the step of patterning the first conductive layer further comprises:
forming a gate at the first area of the substrate.

26. The manufacturing method of the trench LDMOS device as claimed in claim 24, wherein the step of removing the second conductive layer comprises performing a chemical mechanical polishing process.
